(19) United States
(12) Patent Application Publication
(10) Pub. No.: US 2010/0007392 A1
(43) Pub. Date: Jan. 14, 2010

(54) CRYSTAL AUTO-CALIBRATION METHOD AND APPARATUS

(75) Inventors: Hong-Kai HSU, Yonghe City (TW); Chung-Shine HUANG, Yung-Ho City (TW); Wei-Lun WAN, Hsinchu City 300 (TW)

Correspondence Address: LOWE HAUPTMAN HAM & BERNER, LLP, 1700 DIAGONAL ROAD, SUITE 300, ALEXANDRIA, VA, 22314, US

(73) Assignee: MediaTek Inc., Hsinchu (TW)

(21) Appl. No.: 12/170,201

(22) Filed: Jul. 9, 2008

(51) Int. Cl. H03L 7/00

(52) U.S. Cl. 327/160

(57) ABSTRACT

A system for automatically calibrating a crystal of a communication device and a method thereof are described. The system comprises a timing generator for generating a timing signal, a timing adjustment device coupled with the timing generator and for adjusting the timing of the timing signal responsive to receipt of an adjustment signal, and a calibration device coupled with the timing adjustment device and arranged to transmit the adjustment signal responsive to a comparison between the timing signal and a reference signal.

### BACKGROUND

Many wireless communication devices, e.g., BLUETOOTH-based, Global Positioning System (GPS) based, and wireless networking, e.g., WIFI-based, devices, are low cost products. Many of these devices use crystals for generating timing signals in place of oscillators in order to reduce bill of materials cost for the devices.

Timing signals generated using crystals are more inaccurate than timing signals generated using oscillators. For example, the frequency reference requirement for the BLUETOOTH specification provides ±20 parts per million (ppm) tolerance including both static frequency errors and dynamic effects, e.g., due to temperature and aging. In some devices, the dynamic effects of BLUETOOTH clocks is approximately ±10 ppm.

Because of the additional expense, many communication device manufacturers do not set up test instruments on mass production lines, e.g., BLUETOOTH test instruments for error measurement and frequency adjustment. These manufacturers rather sacrifice the quality of the devices. Additionally, some manufacturers do not have the capability to set up and manipulate the test instruments.

### DESCRIPTION OF THE DRAWINGS

One or more embodiments are illustrated by way of example, and not by limitation, in the figures of the accompanying drawings, wherein elements having the same reference numeral designations represent like elements throughout and wherein:

FIG. 1 is a high-level functional block diagram of a communication device comprising a calibration system according to an embodiment;

FIG. 2 is a high-level functional block diagram of a processing device usable in conjunction with an embodiment;

FIG. 3 is a high-level functional process flow according to an embodiment; and

FIG. 4 is a sample timing diagram according to an embodiment.

### DETAILED DESCRIPTION

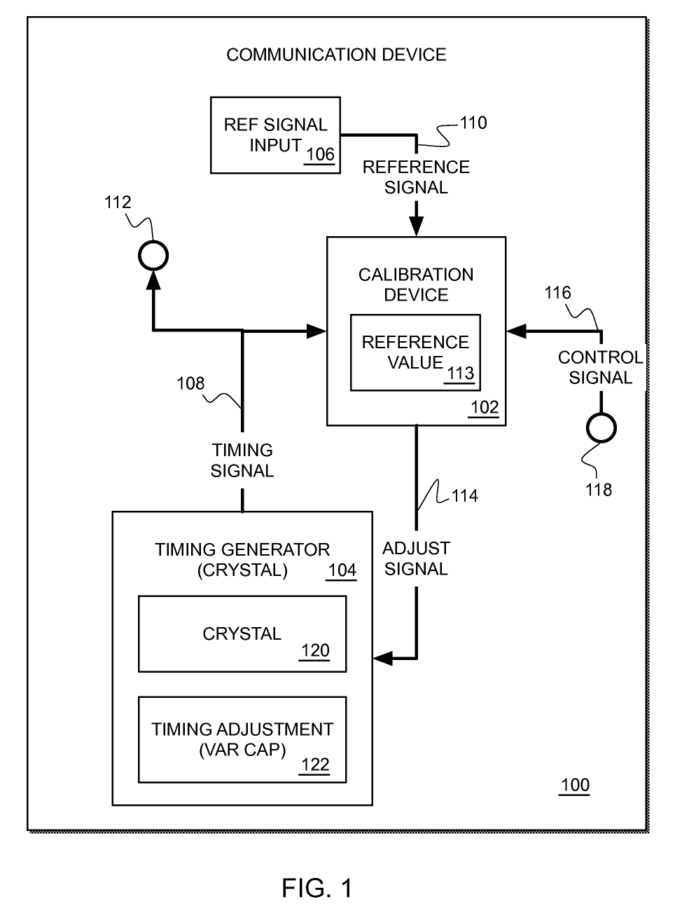

FIG. 1 depicts a high-level functional block diagram of a communication device 100 comprising a calibration device 102 according to an embodiment. In at least some embodiments, communication device 100 comprises a wired and/or wireless communication device, e.g., a cellular or similar telephone, personal digital assistant, or combination thereof, a portable computing or processing platform such as a laptop or hand-held computing device or global positioning satellite (GPS)-based, BLUETOOTH-based, or wireless networking-based device. In at least some embodiments, communication device 100 may be integrated as a part of another device.

Communication device 100 also comprises a timing generator 104 and a reference signal input 106 each of which are communicatively coupled with calibration device 102. In particular, timing generator 104 transmits a timing signal 108 as input to calibration device 102 and reference signal input 106 transmits a reference signal 110 as input to the calibration system. Timing generator 104 also transmits timing signal 108 to one or more devices and/or components of communication device 100 as indicated generically by timing connection 112.

Reference signal input 106 may comprise a pulse-code modulation (PCM) Sync signal received from a communications carrier signal received by communication device 100, a signal received from a general purpose input output (GPIO) of the communication device, a baseband parallel interface (BPI) pin of the communication device, a clock signal of the communication device, and/or a PCM clock signal received from the communications carrier signal received by the communication device.

Calibration device 102 also receives a control signal 116 from a control input 118. In at least some embodiments, control signal 116 is generated internal to communication device 100 and in some alternate embodiments control signal 116 is received from external of the communication device. Control signal 116 comprises one or more control commands which, when received by calibration device 102, cause the calibration device to perform a calibration process to calibrate timing signal 108 generated by timing generator 104. In at least some embodiments, control signal 116 may comprise a start calibration command, a get calibration result command, and a crystal trim command.

In at least some embodiments, the start calibration command causes a reference value 113 to be set in calibration device 102 specifying a number of reference signal 110 cycles are to be counted. In at least some alternate embodiments, reference value 113 is a predetermined value set in calibration device 102 and not via receipt of a start calibration command. In at least some embodiments, the get calibration result command causes the initiation of the counting of the cycles received from reference signal input 106. In at least some embodiments, the crystal trim command causes calibration device 102 to transmit an adjust signal 114 comprising a command causing timing generator 104 to adjust the frequency of timing signal 108.

In at least some embodiments, calibration device 102 operates responsive to one or more commands received via control input 118. In at least some embodiments, calibration device 102 operates automatically based on at least one of a preset periodicity or a detected variance in timing signal 108.

In at least some embodiments, calibration device 102 may comprise an electronic circuit configured to accomplish the functionality according to an embodiment. In at least some alternate embodiments, calibration device 102 may comprise a processor or application specific integrated circuit or an instruction-based device for executing a set of instructions to perform the functionality according to an embodiment.

In at least some embodiments, timing generator 104 transmits more than one timing signal to one or more devices via individual connections, for example for clocking a Bluetooth module or a wireless networking module. In at least some embodiments, timing generator 104 is directly coupled to calibration device 102 and directly transmits timing signal 108 to the calibration device.

Timing generator 104 also receives adjust signal 114 from calibration device 102 to cause the timing generator to adjust, e.g., fine-tune, the frequency of timing signal 108. In at least some embodiments, timing generator 104 is directly coupled to calibration device 102 and directly receives adjust signal 114 from the calibration device.

Timing generator comprises a crystal 120 for use in generating timing signal 108 and a timing adjustment device 122 connected with the crystal and for adjusting the generation of the timing signal by the crystal. Crystal 120, for example a crystal-based oscillator, generates timing signal 108 based on the mechanical resonance of a vibrating crystal of piezoelectric material. In at least some embodiments, crystal 120 may be replaced by an equivalent or similar electric circuit. Adjustment of the capacitance across crystal 120 causes a frequency shift in generated timing signal 108. In at least some embodiments, timing adjustment device 122 comprises a variable capacitor or similar circuit for adjusting the generation of timing signal 108. In at least some embodiments, adjust signal 114 may comprise a predetermined value to which timing adjustment 122 may be set to adjust the generation of timing signal 108.

In at least some embodiments, it is advantageous to tune static frequency errors to a minimal level at the production stage to keep the frequency generated by timing generator 104 within a specification requirement for several years, in order to increase the reliability and extend the life period of the communication devices.

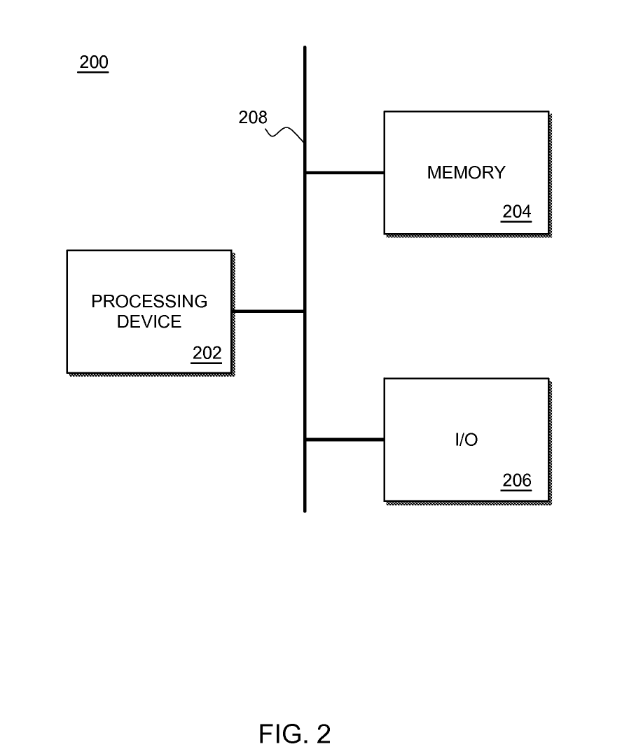

FIG. 2 depicts a high-level functional block diagram of an embodiment 200 of calibration device 102 as a processing device for executing a set of instructions. Embodiment 200 comprises a processing device 202, a memory 204, and an input/output (I/O) device 206 each communicatively coupled with a bus 208. Memory 204 (also referred to as a computer-readable medium) is coupled to bus 208 for storing data, e.g., reference value 113, and instructions to be executed by processing device 202. Memory 204 also may be used for storing temporary variables or other intermediate information during execution of instructions to be executed by processing device 202. Memory 204 may also comprise a read only memory (ROM) or other static storage device coupled to bus 208 for storing static information and instructions for processing device 202.

I/O device 206 may comprise an input device, an output device, and/or a combined input/output device for enabling interaction with calibration device 102.

Operation

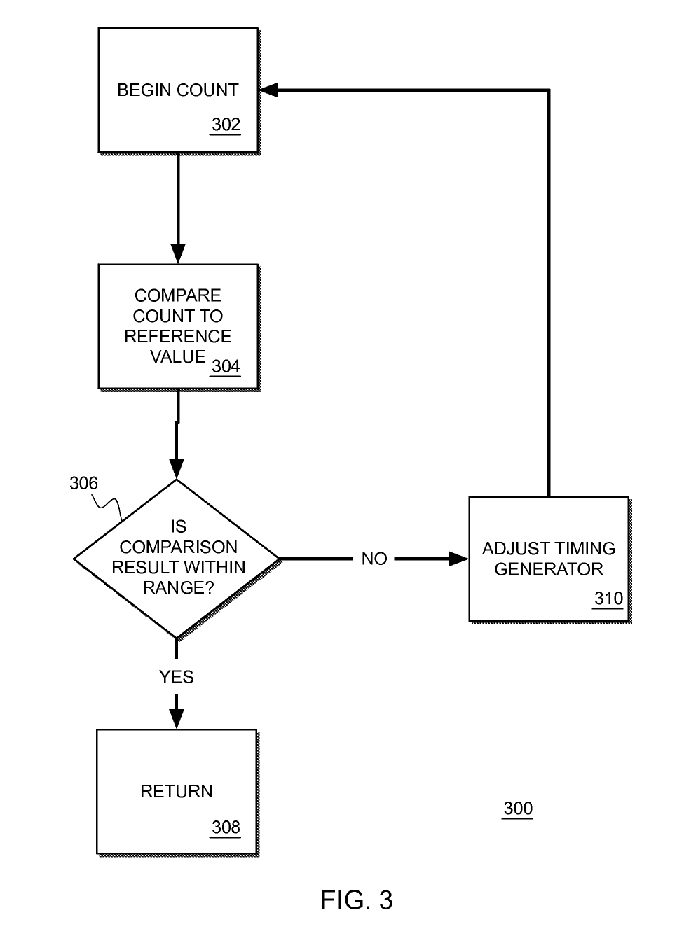

FIG. 3 depicts a high-level functional process flow 300 according to an embodiment. The process flow begins at begin count functionality 302 wherein calibration device 102 begins counting the cycles of reference signal 110 received from reference signal input 106. In at least some embodiments, calibration device 102 begins counting reference signal 110 cycles responsive to receipt of a start calibration command received via control signal 116. In at least some alternate embodiments, calibration device 102 begins counting reference signal 110 cycles automatically, e.g., responsive to passage of a predetermined time period from a last calibration. In at least some embodiments, calibration device 102 begins counting reference signal 110 cycles automatically without receipt of a command from control signal 116. The process flow proceeds to comparison functionality 304.

During comparison functionality 304, calibration device 102 compares the count of reference signal 110 cycles with the reference value 113. In at least some embodiments, the comparison is performed by an arithmetic logic comparison, a subtraction, or other mathematical comparison of the values. The process flow proceeds to result functionality 306.

Based on the result of comparison functionality 304, result functionality 306 causes the process flow to proceed to either return functionality 308 or adjustment functionality 310. If the result of comparison functionality 304 is within a predetermined range (YES), the process flow proceeds to return functionality 308 and the process flow completes. In at least some embodiments, the predetermined range is stored in calibration device 102 similar to reference value 113.

If the result of comparison functionality 304 is not within the predetermined range (NO), the process flow proceeds to adjustment functionality 310. During adjustment functionality 310, calibration device 102 transmits adjust signal 114 to cause timing adjustment 122 of timing generator 104 to modify the generated timing signal 108. For example, calibration device 102 may cause the generation and transmission of adjust signal 114 to timing generator 104 to specify a particular value at which timing adjustment 122 such as an RF register is to be set to adjust timing signal 108 as generated in conjunction with crystal 120. In at least some embodiments, adjust signal 114 comprises an adjust command using a bisection method to adjust timing adjustment 122.

The process flow returns to being count functionality 302 to begin counting the reference signal 110 cycles and perform the calibration process iteratively. In at least some embodiments, following adjustment of timing generator 104 the process flow proceeds to return functionality 308 instead of proceeding to begin count functionality 302. In at least some alternate embodiments, the process flow returns to begin count functionality 302 and perform the calibration process a predetermined number of times.

PCM Sync Signal

Returning now to a particular embodiment using a PCM Sync signal for calibration, particular functionality of process flow 300 of FIG. 3 is described. In a particular embodiment, a calibration of timing generator 104, e.g., a timing generator configured wherein crystal 120 is selected to generate a timing signal frequency of 64 Megahertz (MHz), is performed by calibration device 102 based on the use of PCM Sync signal at 8 kilohertz (KHz) as reference signal 110. In accordance with the process flow of FIG. 3, calibration device 102 begins counting (functionality 302) the number of 64 MHz clock cycles of the timing signal, e.g., the number of transitions from low-to-high during one cycle of reference signal 110, received from the reference signal input 106. Calibration device 102 counts the number of clock cycles received between the desired calibration period of a received PCM Sync signal, e.g., the calibration period can be measured by a specific number of cycles of the PCM Sync signal.

Based on a given desired sample error, the following formula is applied to determine the calibration sample period:

$$\frac{\frac{Allowed Sample Error}{Timing Signal Frequency}}{Calibration Period} = Desired Accuracy ( ppm ) \qquad ( 1 )$$

Assuming an Allowed Sample Error of 2 cycles, i.e., the predetermined range, a Timing Signal Frequency of 64 MHz, and a Desired Accuracy of 5 ppm, then formula (1) provides a calibration period of 400,000 cycles (which is 50 cycles of the PCM sync signal) or 6.25 milliseconds (ms).

Reference value 113 is set to 400,000 and is compared (functionality 304) to the count of the timing signal 108 during the above calibration period, i.e., 6.25 ms. In at least some embodiments, calibration device 102 subtracts the count of timing signal from reference value 113 and compares (functionality 306) the result to the predetermined range, i.e., the allowed sample error, for example plus or minus 1, and based on the comparison result proceeds to either return, indicating timing generator 104 is calibrated (functionality 308) or proceeds to adjust the timing generator indicating the timing generator is not calibrated (functionality 310).

In at least some embodiments, adjustment of timing generator 104 is performed using interpolation. In at least some other embodiments, the adjustment is performed based on a lookup table or a predetermined formula. In at least some embodiments, if the result of comparison functionality 306 exceeds a predetermined maximum deviation, for example 50, the flow proceeds to an error state indicating a problem with timing generator 104 which cannot be adjusted using calibration device 102.

In at least one embodiment, communication device 100 is manufactured on a mass production line and a calibration tool is used to calibrate the communication device. In accordance with the mass production embodiment, the calibration tool communicates with calibration device 102 via transmission of commands via control signal input 118 and receipt of data via the control signal input. In at least this embodiment, control signal input 118 is both an input and output device.

The calibration tool transmits a start calibration command in a control signal 116 to cause calibration device 102 to proceed through process flow 300 (FIG. 3) and report the calibration information, e.g., the count of timing signal 108 and/or the result of comparison functionality 306. Based on the received calibration information, the calibration tool either causes calibration device 102 to stop the calibration or to adjust timing generator 104 (adjust functionality 310). In at least some embodiments, the calibration tool again transmits the start calibration command and performs the process flow 300.

In at least some embodiments, the calibration tool is connected via a wired connection to the communication device on the mass production line in order to communicate with calibration device 102.

In at least some alternate embodiments, an end-user of communication device 100 initiates use of the communication device and causes calibration device 102 to perform the calibration process, e.g., process flow 300 (FIG. 3). In at least some embodiments a dealer, e.g., prior to delivery to an end-user, may initiate use of the communication device and cause calibration device 102 to perform the calibration process.

GPIO

In accordance with another particular embodiment, a GPIO pin is used for generating reference signal 110 provided to calibration device 102. In operation, calibration device 102 monitors the GPIO pin input and increments a counter during a calibration period in which the GPIO pin is set to high. The number of instructions and memory cycles used by calibration device 102 performing the counting is calculated and returned, e.g., via a host control interface of device 100, to a calibration tool.

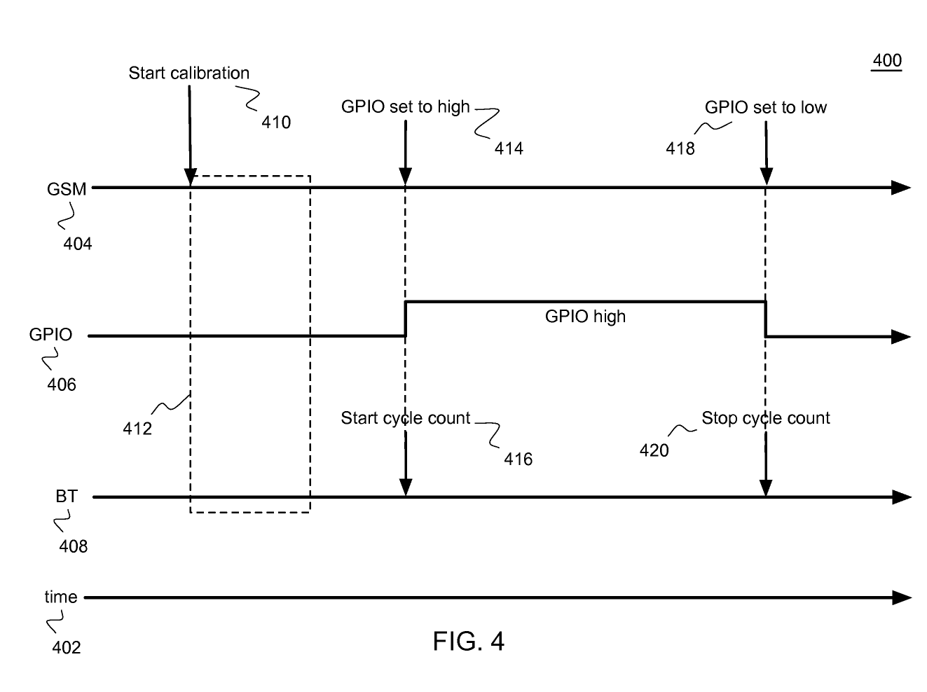

FIG. 4 depicts a sample timing diagram 400 representing the use of a reference signal output from a GPIO for calibration. The timing diagram is not necessarily drawn to scale.

Timing diagram 400 represents signal timing with reference to the passage of time as indicated by reference line 402 extending horizontally. In particular, timing diagram 400 comprises a GSM signal 404 indicating the generation of signals with respect to controlling a reference signal, in this case GPIO signal 406, used to calibrate a particular communication device. Timing diagram 400 further comprises a calibration device, in this case a BLUETOOTH-based (BT) calibration device 408, to be calibrated with reference to GPIO signal 406.

GSM signal 404 indicates a start calibration signal 410 to communication device 100 causing the communication device to perform setup and/or synchronization operations (during a period indicated by reference numeral 412) prior to calibration process flow 300. After period 412, GSM signal 404 indicates a GPIO set to high signal 414 being transmitted to cause GPIO signal 406 to transition to a high state. Transition of GPIO signal 406 to high state causes BT 408 to begin counting (indicated by start cycle count reference 416) the number of cycles of timing signal 108.

After a predetermined calibration period, GSM signal 404 indicates a PIO set to low signal 418 being transmitted to cause GPIO signal 406 to transition to a low state. Transition of GPIO signal 406 to low state causes BT 408 to stop counting (indicated by stop cycle count reference 420) the number of cycles of timing signal 108. Based on at least the number of cycles counted, calibration device 102 performs the remainder of process flow 300.

BPI

Similar to GPIO, a baseband parallel interface (BPI) pin of communication device 100 may be used as the reference signal input 106 in order to calibrate timing generator 104 as described. The communication device 100 may program the time period of BPI signal to high or low in advance of calibration being performed.

Second Clock Source

In at least some other embodiments, a second clock source, e.g., a GSM 32 KHz clock pin of communication device 100 or a PCM Clock signal of the communication device 100 may be used as the reference signal input 106 in order to calibrate timing generator 104 as described.

What is claimed is:

1. A system for automatically calibrating a crystal of a communication device, comprising:
a timing generator for generating a timing signal;
a timing adjustment device coupled with the timing generator and for adjusting the timing of the timing signal responsive to receipt of an adjustment signal; and
a calibration device coupled with the timing adjustment device and arranged to count a number of timing signal cycles received with reference to a calibration period defined by a reference signal, compare a difference between a reference value and the count, and transmit the adjustment signal responsive to the comparison result.

2. The system as claimed in claim 1, wherein the reference signal comprises at least one of a pulse-code modulation (PCM) Sync signal, a signal received from a general purpose input output (GPIO) of the communication device, a baseband parallel interface pin of the communication device, a clock signal of the communication device, and/or a PCM clock signal received from a communications carrier signal received by the communication device.

3. The system as claimed in claim 1, wherein the timing generator comprises the timing adjustment device.

4. The system as claimed in claim 1, wherein the calibration device receives a control signal for configuring a comparison criterion with respect to the reference signal received by the calibration device.

5. The system as claimed in claim 1, wherein the calibration period is based on a number of cycles of the reference signal received.

6. The system as claimed in claim 1, wherein the calibration device is arranged to compare the difference between the reference value and the count with a predetermined range.

7. The system as claimed in claim 6, wherein the calibration device is arranged to transmit the adjustment signal if the difference is outside the predetermined range.

8. A method of automatically calibrating a crystal of a communication device, comprising:
receiving a timing signal from a timing generator;
receiving a reference signal;
comparing the reference signal with the timing signal by counting a number of timing cycles received within a calibration period; and
adjusting the timing signal based on the result of the comparison;
wherein the calibration period is defined by a number of cycles of the reference signal.

9. The method as claimed in claim 8, wherein the reference signal comprises at least one of a pulse-code modulation (PCM) Sync signal, a signal received from a general purpose input output (GPIO) of the communication device, a baseband parallel interface pin of the communication device, a clock signal of the communication device, and/or a PCM clock signal received from a communications carrier signal received by the communication device.

10. The method as claimed in claim 8, wherein adjusting the timing signal comprises transmitting an adjustment signal to cause adjustment of a timing adjustment device.

11. The method as claimed in claim 8, wherein adjusting the timing signal comprises adjusting a timing adjustment device arranged to cause a change in frequency of a crystal connected to the timing adjustment device.

12. The method as claimed in claim 8, wherein the calibration period is based on an allowed sample error.

13. The method as claimed in claim 8, wherein comparing the reference signal further comprises comparing the difference between a reference value and the count with a predetermined range.

14. The method as claimed in claim 13, wherein comparing the reference signal causes the adjusting the timing signal if the difference is outside the predetermined range.

15. The method as claimed in claim 8, further comprising receiving a control signal for configuring a comparison criterion with respect to the reference signal.

16. A computer-readable medium storing instructions which, when executed by a processor, cause the processor to receive a timing signal from a timing generator; receive a reference signal; compare the reference signal with the timing signal by counting a number of timing cycle received within a calibration period; and adjust the timing signal based on the result of the comparison; wherein the calibration period is defined by a number of cycles of the reference signal.

17. The medium as claimed in claim 16, wherein the reference signal comprises at least one of a pulse-code modulation (PCM) Sync signal, a signal received from a general purpose input output (GPIO) of the communication device, a baseband parallel interface pin of the communication device, a clock signal of the communication device, and/or a PCM clock signal received from a communications carrier signal received by the communication device.

18. The medium as claimed in claim 16, wherein adjusting the timing signal comprises adjusting to cause a change in frequency of a crystal.

19. The medium as claimed in claim 16, wherein the calibration period is based on an allowed sample error.

20. A mass production method of calibrating a crystal of a communication device, comprising:
receiving a communication device on a production line;
connecting the communication device with a calibration tool;
transmitting a start calibration command from the calibration tool to the communication device causing the communication device to count a timing signal from a timing generator with reference to a received reference signal; and
transmitting an adjustment command from the calibration tool to the communication device, responsive to receipt of the count from the communication device, if a comparison of the timing signal with a reference value is outside a predetermined range.
